(19) United States
(12) Patent Application Publication
(10) Pub. No.: US 2016/0187643 A1
(43) Pub. Date: Jun. 30, 2016

(54) Micro-Electromechanical System (MEMS) Devices and Methods for Packaging the Same

(71) Applicant: Lexmark International Inc., Lexington, KY (US)

(72) Inventors: James Ronald Booth, Nicholasville, KY (US); Roger Steven Cannon, Nicholasville, KY (US); Martin C. Klement, Lexington, KY (US)

(21) Appl. No.: 14/588,010

(22) Filed: Dec. 31, 2014

(51) Int. Cl. G02B 26/08; B81B 7/00; G02B 26/10

(52) U.S. Cl. CPC G02B 26/085; G02B 26/101; B81B 7/0038

(57) ABSTRACT

An assembly for a micro-electromechanical system (MEMS) device includes a sealed enclosure, a MEMS component disposed within the sealed enclosure, and a transformer arrangement. The transformer arrangement includes a first wire coil disposed outside the sealed enclosure, and a second wire coil disposed within the sealed enclosure and coupled to the MEMS component, the first and second wire coils being mutually inductively coupled to each other. Upon applying energy to the first wire coil outside the sealed enclosure, electrical energy is induced in the second wire coil within the sealed enclosure which is used to drive the MEMS component.

### CROSS REFERENCES TO RELATED APPLICATIONS

None.

### STATEMENT REGARDING FEDERALLY SPONSORED RESEARCH OR DEVELOPMENT

None.

### REFERENCE TO SEQUENTIAL LISTING, ETC.

None.

### BACKGROUND 1. Field of the Disclosure

The present disclosure relates generally to micro-electromechanical systems (MEMS) and, more particularly, to MEMS devices and methods for packaging the same.

2. Description of the Related Art

Recently, MEMS devices have been widely used in many applications as replacements for conventional components because of their compact size, light weight, reliability, and relatively lower cost of manufacturing. In some imaging applications that employ optical scanning systems, for example, oscillating MEMS mirror devices have been used to replace traditional rotating polygon minors as MEMS minors provide potential advantages of higher scanning speeds, smaller sizes and weights, and reduced costs, among others.

A MEMS mirror device typically includes a mirror fabricated on a semiconductor die using microfabrication techniques. In operation, energy is applied to the MEMS mirror device to allow its mirror to oscillate at a particular frequency. A light source illuminates a light beam on the mirror such that as the mirror oscillates, the light beam is scanned bidirectionally in both forward and reverse directions across a target image plane surface, such as photosensitive member in electrophotographic imaging devices.

The extent of motion or oscillation of a MEMS mirror device in response to a given drive energy is determined at least in part by the mirror device's quality factor (Q). One source of reduction in quality factor (Q) is the damping effect of air resistance induced by the mirror's oscillation. As the mirror becomes larger and/or oscillates faster, reduction of Q may result in greater drive energy and greater jitter for a given oscillation angle. To reduce this damping effect, some MEMS mirror devices are operated at very low air pressures by packaging them in an inert atmosphere or vacuum.

In some existing package designs, a MEMS mirror die is mounted within a vacuum sealed package. In order to drive the mirror, direct electrical connections between the MEMS mirror die and external drive electronics are typically established. Ceramic substrates may be used in or as part of MEMS mirror packages because its thermal expansion characteristics closely match that of a semiconductor material, such as silicon typically used to fabricate a MEMS die, and because vacuum tight electrical connections can be achieved through the ceramic substrate. However, ceramic substrates are generally expensive and the processes involved for establishing complex structures, such as the electrical connections through the ceramic substrate, require complex fabrication techniques that are often difficult to manufacture at low costs. To some extent, this has prevented or discouraged use of MEMS devices in various applications.

### SUMMARY

Example embodiments of the present disclosure provide a cost-efficient means for packaging MEMS devices.

In one example embodiment, a scanning device includes an enclosure maintaining a substantially fixed pressure level therein and having a window for allowing light to enter and exit the enclosure. A MEMS mirror for reflecting light incident thereon is disposed within the enclosure. The scanning device further includes a transformer having a first wire coil disposed outside the enclosure, and a second wire coil disposed within the enclosure and electrically coupled to the MEMS mirror. The transformer is used deliver electrical power to the MEMS mirror to drive the MEMS mirror.

In another example embodiment, an assembly for a micro-electromechanical system (MEMS) device includes a sealed enclosure, a MEMS component disposed within the sealed enclosure, and a transformer arrangement. The transformer arrangement has a first wire coil disposed outside the sealed enclosure, and a second wire coil disposed within the sealed enclosure and coupled to the MEMS component, the first and second wire coils being mutually inductively associated with each other. In operation, applying energy to the first wire coil outside the sealed enclosure induces electrical energy in the second wire coil within the sealed enclosure for use by the MEMS component.

### BRIEF DESCRIPTION OF THE DRAWINGS

The above-mentioned and other features and advantages of the disclosed example embodiments, and the manner of attaining them, will become more apparent and will be better understood by reference to the following description of the disclosed example embodiments in conjunction with the accompanying drawings, wherein:

FIG. 1 is a side elevational view of an image forming apparatus according to an example embodiment;

FIG. 2 illustrates a schematic layout of a laser scanning unit of the image forming apparatus in FIG. 1 according to an example embodiment;

FIG. 3 is a perspective view of a MEMS mirror die according to an example embodiment;

FIG. 4 is a schematic diagram illustrating a packaging assembly for a MEMS device according to an example embodiment;

FIG. 5 is a schematic diagram illustrating a packaging assembly for a MEMS device according to another example embodiment;

FIGS. 6A-6C are schematic diagrams illustrating circuitry appearing in the packaging assembly of FIG. 5;

FIG. 7 is a perspective view of a packaged MEMS mirror device according to an example embodiment;

FIG. 8 is an exploded perspective view of the MEMS mirror device in FIG. 5;

FIG. 9 illustrates a primary coil on a printed circuit board of the MEMS mirror device in FIG. 6;

FIG. 10 illustrates a secondary coil coupled to a MEMS mirror die of the MEMS mirror device in FIG. 6; and

FIG. 11 illustrates the MEMS mirror device in FIG. 8 having a tilted top, in accordance with an example embodiment of the present disclosure.

### DETAILED DESCRIPTION

It is to be understood that the present disclosure is not limited in its application to the details of construction and the arrangement of components set forth in the following description or illustrated in the drawings. The present disclosure is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings. In addition, the terms “connected” and “coupled” and variations thereof are not restricted to physical or mechanical connections or couplings.

Spatially relative terms such as “top”, “bottom”, “front”, “back” and “side”, and the like, are used for ease of description to explain the positioning of one element relative to a second element. Terms such as “first”, “second”, and the like, are used to describe various elements, regions, sections, etc. and are not intended to be limiting. Further, the terms “a” and “an” herein do not denote a limitation of quantity, but rather denote the presence of at least one of the referenced item.

Furthermore, and as described in subsequent paragraphs, the specific configurations illustrated in the drawings are intended to exemplify embodiments of the disclosure and that other alternative configurations are possible.

Reference will now be made in detail to the example embodiments, as illustrated in the accompanying drawings. Whenever possible, the same reference numerals will be used throughout the drawings to refer to the same or like parts.

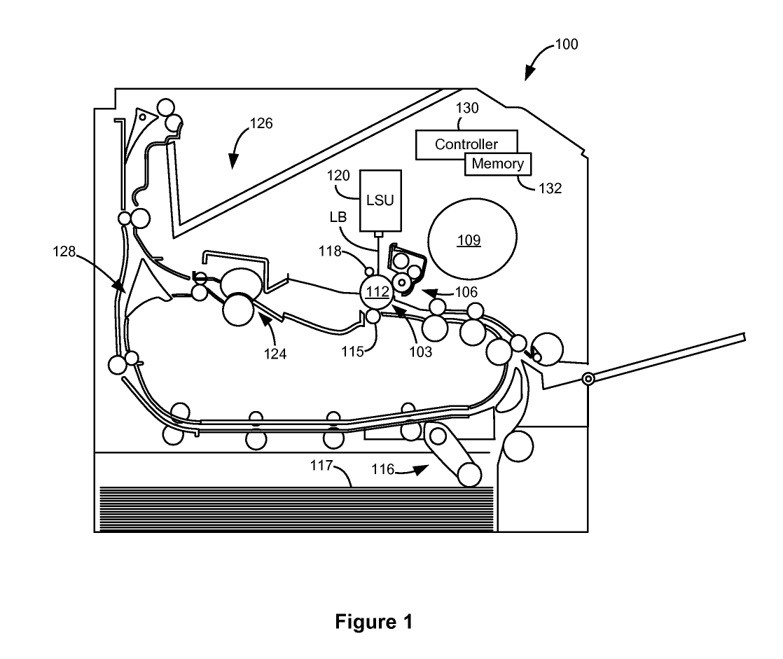

FIG. 1 illustrates an image forming device 100 according to an example embodiment. Image forming device 100 may include a toner transfer area 103 having a developer unit 106 that is operably connected to a toner reservoir 109 for receiving toner for use in a printing operation. Toner reservoir 109 is controlled to supply toner as needed to developer unit 106. Developer unit 106 is associated with a photoconductive member 112 that receives toner therefrom during toner development to form a toned image thereon. Photoconductive member 112 is paired with a transfer member 115 for use in transferring toner to a sheet of print media that is picked by a pick assembly 116 from a media stack 117 and fed through toner transfer area 103 between photoconductive member 112 and transfer member 115.

During image formation, the surface of photoconductive member 112 is charged to a specified voltage, such as −800 volts, for example, by a charge roller 118. At least one light beam LB from a laser scanning unit (LSU) 120 is directed to the surface of photoconductive member 112 and discharges those areas it contacts to form a latent image thereon. In one example embodiment, areas on the photoconductive member 112 illuminated and impinged by the light beam LB are discharged to approximately −100 volts. The developer unit 106 then transfers toner to photoconductive member 112 to form a toner image thereon. The toner is attracted to the areas of the surface of photoconductive member 112 that are discharged by the light beam LB from LSU 120. In one example embodiment, a positive voltage field formed in part by transfer member 115 attracts the toner image from photoconductive member 112 to the media sheet between the photoconductive member 112 and transfer member 115.

A fuser assembly 124 is disposed downstream of toner transfer area 103 and receives media sheets with the unfused toner images superposed thereon. In general terms, fuser assembly 124 applies heat and pressure to the media sheets in order to fuse toner thereto. After leaving fuser assembly 124, a media sheet is either deposited into output media area 126 or enters duplex media path 128 for transport to toner transfer area 103 for imaging on a second surface of the media sheet.

Image forming device 100 is depicted in FIG. 1 as a monochrome laser printer which utilizes only a single developer unit 106 and photoconductive member 112 for depositing black toner to media sheets. In other embodiments, image forming device 100 may be a color laser printer having four photoconductive members, each corresponding to an associated one of cyan, yellow, magenta, and black image planes, and one or more LSUs for outputting light beams toward corresponding photoconductive members to form latent images on each photoconductive member. Toner may be transferred to a media sheet in a single step process—from the plurality of photoconductive members directly to a media sheet. Alternatively, toner may be transferred from each photoconductive member onto an intermediate transfer member in a first step, and from the intermediate transfer member to a media sheet in a second step. Further, image forming device 100 may be part of a multi-function product having, among other things, an image scanner for scanning printed sheets.

Image forming device 100 further includes a controller 130 and memory 132 communicatively coupled thereto. Though not shown in FIG. 1, controller 130 may be coupled to components and modules in image forming device 100 for controlling same. For instance, controller 130 may be coupled to toner reservoir 109, developer unit 106, photoconductive member 112, fuser assembly 124 and/or LSU 120 as well as to motors (not shown) for imparting motion thereto. It is understood that controller 130 may be implemented as any number of controllers and/or processors for suitably controlling image forming device 100 to perform, among other functions, printing operations.

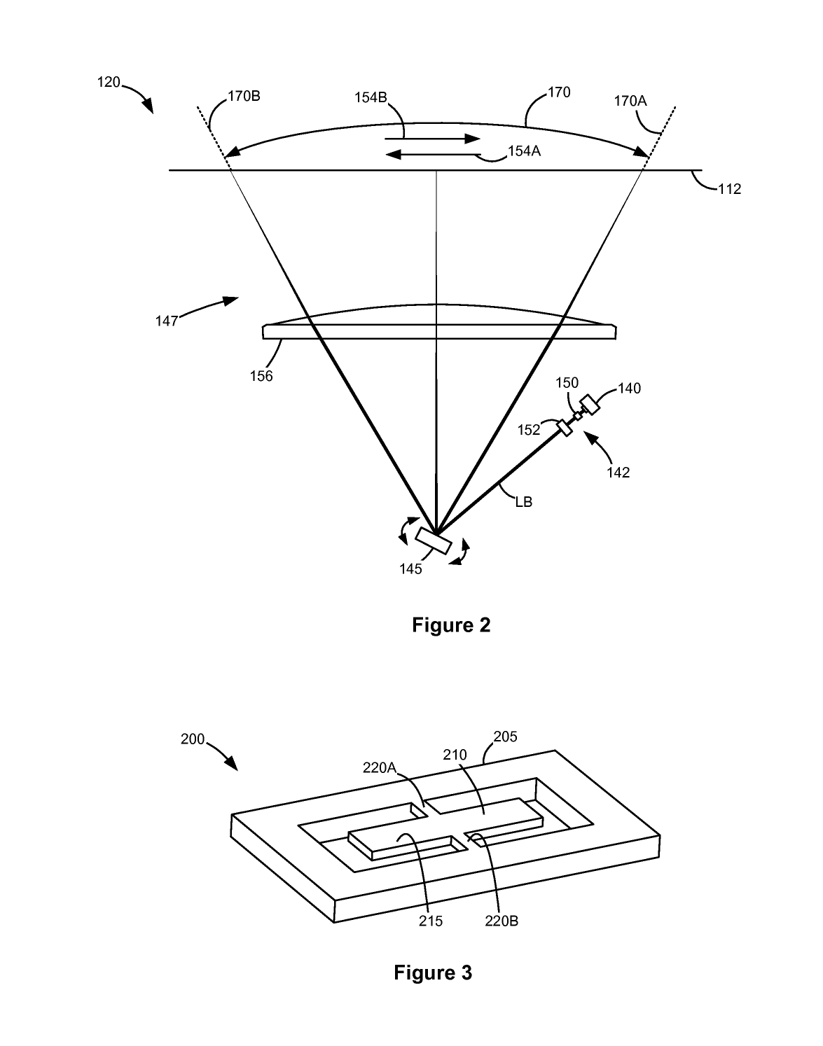

Referring to FIG. 2, a schematic layout of LSU 120 is shown according to an example embodiment. LSU 120 may include a light source 140, pre-scan optics 142, a scanning device 145, and post-scan optics 147.

Light source 140 may emit a light beam LB and may be implemented, for example, using a laser diode or any other suitable device for generating a beam of light. LSU 120 may also include driver circuitry (not shown) communicatively coupled to controller 130 for receiving video/image information and/or control data that may be utilized to set and/or vary the laser power used by light source 140. In the example embodiment illustrated in FIG. 2, a single light source 140 generates a single light beam LB. It is understood that other embodiments of LSU 120 may include a plurality of light sources 140 for generating a plurality of light beams LB. Such other embodiments may include additional pre-scan optics 142 as needed to direct and condition the plural light beams.

Pre-scan optics 142 may include a collimating lens 150 for collimating light beam LB emitted by light source 140, and/or a pre-scan lens 152 to direct and focus the collimated light beam LB towards scanning device 145.

Scanning device 145 may include at least one reflective surface for receiving and reflecting light incident thereon. In the example shown, scanning device 145 comprises a bidirectional scanning oscillator, such as a torsion oscillator or resonant galvanometer, controlled to operate bidirectionally at a scanning frequency to scan light beam LB emitted by light source 140 and create scan lines on the surface of photoconductive member 112 in both forward direction 154A and reverse direction 154B along a main scan direction.

Post-scan optics 147 may include a post-scan lens 156 used to focus light beam LB onto the surface of photoconductive member 112. It will be appreciated, though, that other optical elements may be included downstream scanning device 145, relative to the optical path of light beam LB, such as mirrors, other lenses, and sensors used for synchronization.

During an imaging operation, image data corresponding to an image to be printed may be converted by controller 130 into modulation data. The modulation data may be utilized by the driver circuitry to modulate light source 140 so that LSU 120 outputs modulated light beam LB. Light beam LB emitted from light source 140 may be collimated by collimation lens 150 and pass through pre-scan lens 152 so that light beam LB converges to strike the reflective surface of scanning device 145. Scanning device 145 may direct portions of light beam LB modulated with image data toward the surface of photoconductive member 112 through a scan angle 170 defined by scan positions 170A and 170B. Post-scan lens 156 may transform the rotational scan of light beam LB reflected from scanning device 145 into a substantially linear scan of light beam LB at the surface of photoconductive member 112, with substantially linear scan velocity, and with substantially uniform light beam spot size along the surface of photoconductive member 112.

As photoconductive member 112 rotates, a plurality of scan lines may be formed, creating a latent image on the surface of photoconductive member 112. In the example embodiment, the plurality of scan lines may comprise alternating forward and reverse scan lines occurring in the forward and reverse directions 154A and 154B, respectively, due to the nature of scanning using a bidirectional scanning oscillator.

According to example embodiments, scanning device 145 may be implemented as a MEMS device having a MEMS mirror component or die that is fabricated on a semiconductor wafer. FIG. 3 illustrates an example MEMS mirror die 200. MEMS mirror die 200 is typically formed from semiconductor materials using different techniques of microfabrication, such as doping or ion implantation, etching, deposition of various materials, photolithography, and/or others. In the example shown, MEMS mirror die 200 may include a frame 205 and a mirror 210. In particular, it may include a central rectangular plate 215, which includes mirror 210 or similar reflective surface, suspended by two extensions 220A, 220B which may be integral with the surrounding frame 205. Typically, central plate 215, extensions 220, and frame 205 are cut or etched from a single silicon wafer. It will be appreciated, though, that the architecture of the MEMS mirror die 200 as described herein is only for purposes of illustration and that other designs of a MEMS mirror die 200 may be implemented. For example, other designs considering use of a plurality of torsion arms to allow tilting and oscillation a MEMS mirror along multiple axes are contemplated.

A number of actuation methods may be used to drive the mirror 210 to oscillate about the axis defined by extensions 220 to bidirectionally scan light beam LB across the surface of photoconductive member 112, such as, for example, magnetic, or thermal actuation. Accordingly, MEMS mirror die 200 may include other electrical circuitries or components used for actuation which may be fabricated using different conventional integrated circuit (IC) fabrication methods. Further, MEMS mirror die 200 may also include other electronics and components for receiving and/or transforming energy into a form suitable for driving oscillation of the mirror 210.

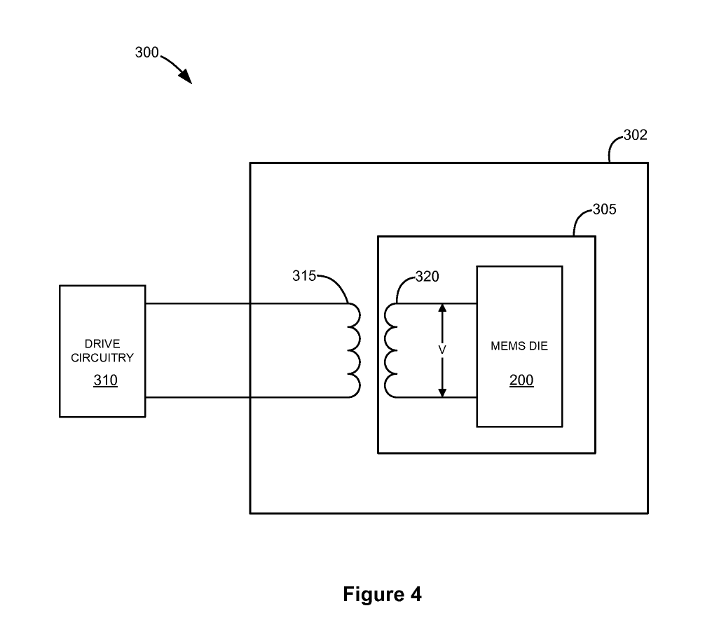

In order to achieve an operating environment with a relatively very low air pressure so as to reduce damping effects on MEMS mirror die 200, MEMS mirror die 200 may be packaged within an enclosure sealed near or at vacuum pressure. In accordance with example embodiments of the present disclosure, MEMS mirror die 200 may be packaged in a manner that bypasses the need to pierce through the sealed enclosure when establishing electrical connections with an external drive circuitry. FIG. 4 illustrates a general concept of packaging a MEMS mirror assembly 300 that may be used to achieve the aforementioned features.

As shown, MEMS mirror assembly 300 is disposed in a package 302 which includes a sealed enclosure 305. Pressure level within the sealed enclosure 305 may be kept near or at vacuum conditions so as to allow the MEMS mirror die 200 to operate with substantially reduced damping effect. In another example embodiment, a gas, such as Argon gas, is placed in sealed enclosure 305 so that pressure is maintained at a substantially constant level, but not necessarily at or near vacuum. Such an implementation provides an advantage of providing a substantially constant pressure, dust free environment for MEMS mirror assembly 300, without stressing package 302 as seen in maintaining vacuum conditions. A power source in the form of external drive circuitry 310 may be used to provide energy to MEMS mirror assembly 300 to drive the mirror 210 of MEMS mirror die 200 to oscillate. To avoid having to pierce through any wall of the sealed enclosure 305 for power delivery, power may be delivered into the sealed enclosure via mutual inductance. In particular, a first coil 315 may be disposed outside the sealed enclosure 305 and a second coil 320 may be disposed within sealed enclosure 305. The first coil 315 is electrically coupled to drive circuitry 310 to receive energy therefrom. The second coil 320 within the sealed enclosure 305 is arranged to be mutually inductively associated with the first coil 315 such that current variations introduced by the drive circuitry 310 in the first coil 315 induces a voltage V across the ends of the second coil 320 through electromagnetic induction. As such, the first coil 315 and the second coil 320 may form a transformer arrangement with the first coil 315 acting as a primary winding of the transformer and providing electrical power to the MEMS mirror die 200 via the second coil 320. The ratio between the number of turns of the first coil 315 to the numbers of turns of the second coil 320 may be used to either boost or reduce the voltage V presented to the MEMS mirror die 200, depending on the design contemplated. The induced voltage V may be applied to the MEMS mirror die 200 which in turn may use the applied voltage to drive its mirror to oscillate. MEMS mirror die 200 may include additional circuitry for converting the induced voltage V into a form suitable for driving its mirror to oscillate.

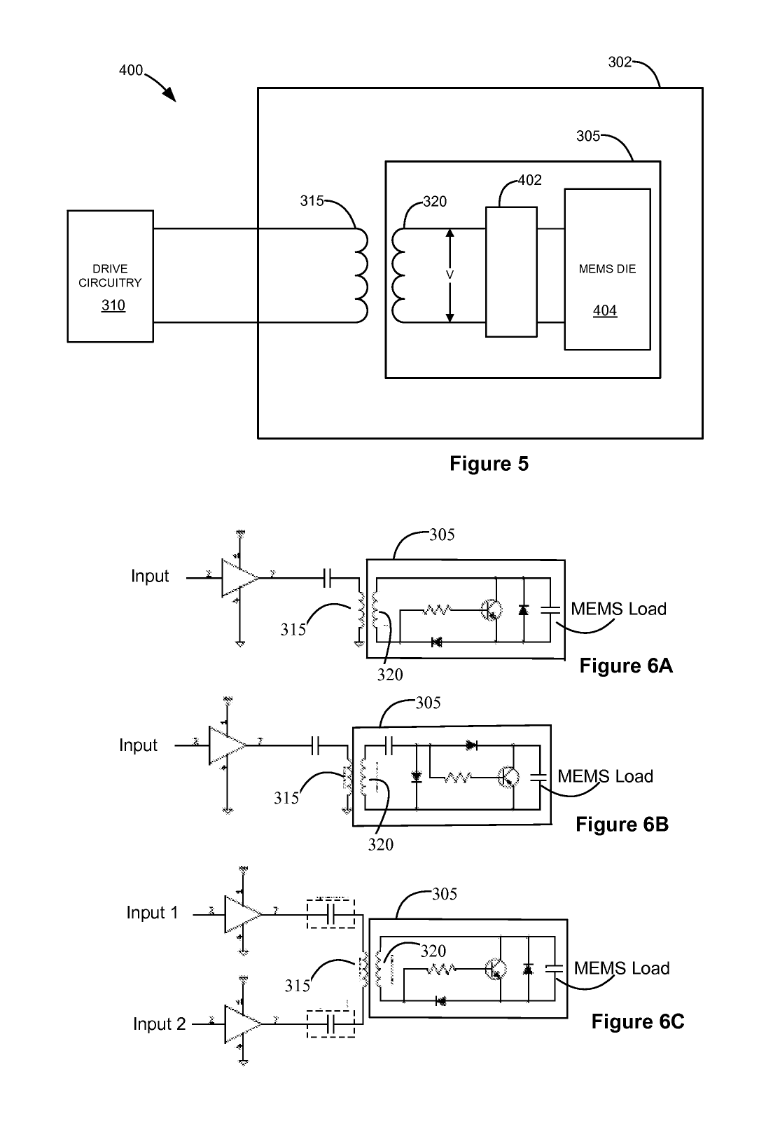

FIG. 5 illustrates MEMS assembly 400 according to another example embodiment. MEMS assembly 400 differs from MEMS mirror assembly 300 by including circuit 402 which is disposed between second coil 320 and MEMS die 404. Circuit 402 may provide energy to MEMS die 404 to deflect the mirror and withdraw energy from MEMS die 404 to harvest mechanical energy stored therein, for suitably controlling MEMS die 404. Circuit 402 may include passive electrical components, active electrical components or both. The electrical components may be integrated on one or more circuit die, be discrete components, or both. Though circuit 402 is shown as being within sealed enclosure 305, some or all of circuit 402 may be disposed external thereto. FIGS. 6A-6C show three example implementations of circuit 402, in which the loading of MEM die 404 is represented as a capacitor. FIGS. 6A and 6B illustrate single driver circuits for circuit 402 and FIG. 6C illustrate a double driver circuit. Circuit 402 of FIG. 6C includes two optional capacitors coupled to first coil 315.

In one embodiment, MEMS die 404 is a MEMS torsion mirror device as described above with respect to MEMS mirror die 200, for use as a resonant oscillator in an optical system such as LSU 120. It is understood that MEMS die 404 may be an electrostatic, piezoelectric, or electromagnetic MEMS device. MEMS assembly 400 may be used in optical systems other than LSU 120. In this regard, MEMS die 404 may be any optical MEMS device that diffracts, refracts and/or reflects light. For example, MEMS die 404 may be a deformable MEMS mirror. A deformable MEMS mirror allows for the divergence/convergence of a reflected beam of light to be changed. Because deformable MEMS mirrors and other MEMS optical devices are well known, a detailed discussion thereof will not be presented for reasons of simplicity. Though the discussion hereinbelow is described with respect to MEMS mirror die 200 and MEMS mirror assembly 300, it is understood that MT MS die 404 and MEMS assembly 400 may be similarly employed.

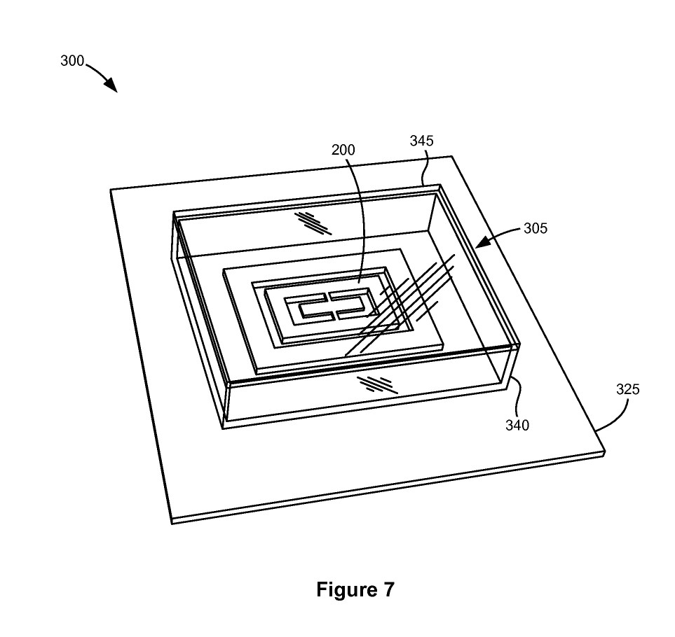

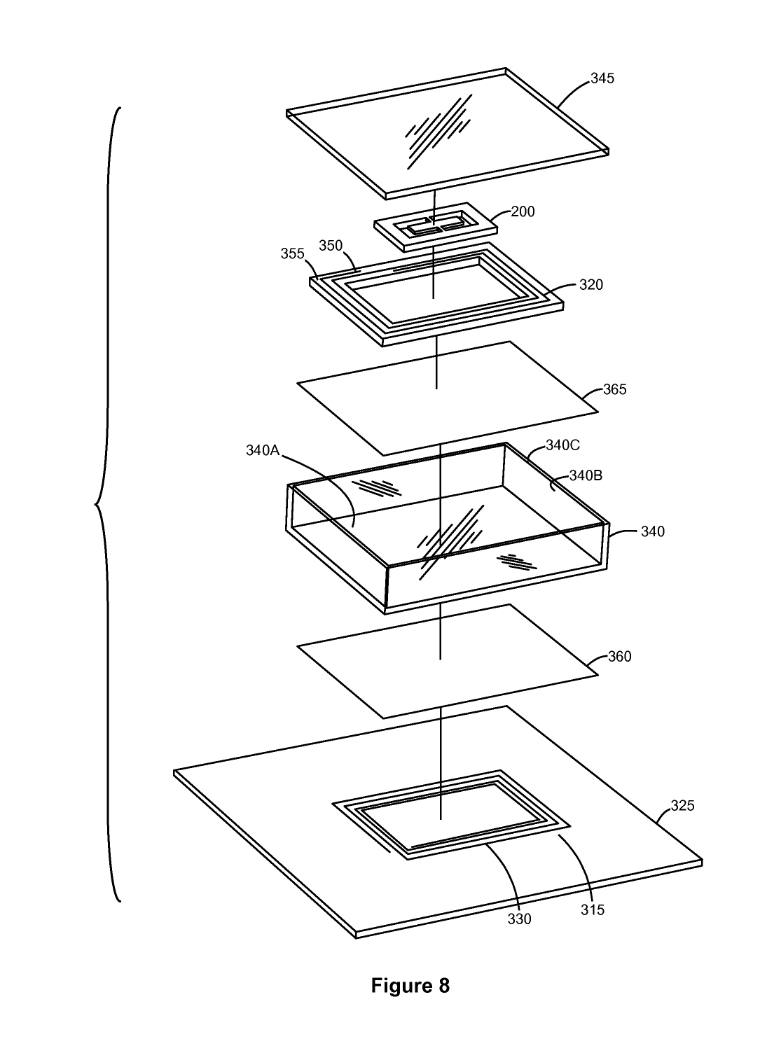

FIG. 7 illustrates a representative embodiment of MEMS mirror device 300 that is packaged in accordance with example embodiments. As shown, MEMS mirror device 300 includes a printed circuit board (PCB) 325, sealed enclosure 305 mounted on PCB 325, and MEMS mirror die 200 disposed within sealed enclosure 305. Generally, PCB 325 is a board on which various electrical parts and components, such as integrated components and discrete components (e.g., transistors, resistors, electrical conductors, etc.) may be disposed. In an example embodiment, PCB 325 may include the first coil 315. Sealed enclosure 305 may include therein the second coil 320. Sealed enclosure 305 may be formed from a non-metallic material so as to prevent distortion of magnetic fields between the first coil 315 on the PCB 325 and the second coil 320 disposed within sealed enclosure 305 so as to ensure reliable transformer operation.

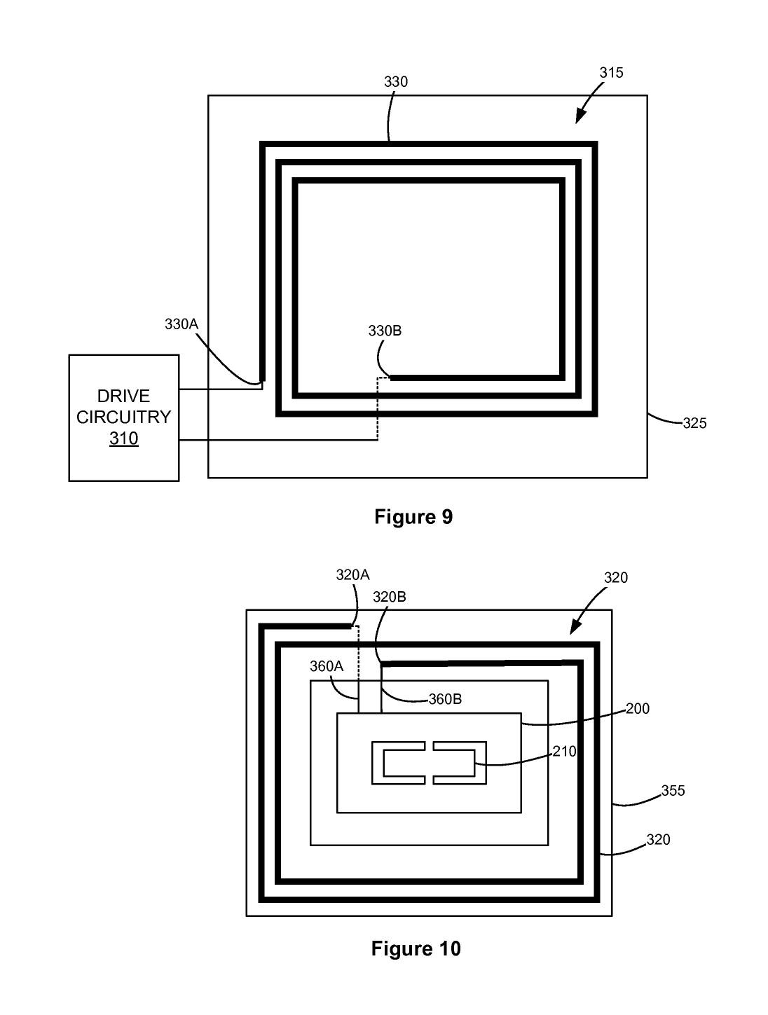

FIG. 8 illustrates an exploded perspective view of MEMS mirror device 300 shown in FIG. 7. On PCB 325, the first coil 315 is shown as being formed by winding a conductive wire 330 to extend radially about a central portion of PCB 325 (also shown in more detail in FIG. 9). As an example, wire 330 may be formed on PCB 325 by etching a metal layer using conventional methods. It will be appreciated, though, that other techniques may be used to provide first coil 315 externally from sealed enclosure 305 and/or on PCB 325, and that first coil 315 may follow other wiring patterns and/or be located elsewhere on PCB 325. The first coil 315 serves as the primary coil for the transformer arrangement and may be connected to drive circuitry 310 to receive energy therefrom via end terminals 330A, 330B (FIG. 9). Connection to drive circuitry 310 may utilize known techniques for connecting to a signal or wire segment on a PCB.

Sealed enclosure 305 may comprise a receptacle 340 and a window 345. Receptacle 340 includes a base 340A and side walls 340B. Window 345, on the other hand, may be sized to cover the open surface of receptacle 340 in sealing engagement with the top rim 340C of side walls 340B to form or define a volume under reduced pressure, relative to atmospheric pressure, or partial vacuum. MEMS mirror die 200 and the second coil 320 may be disposed within the sealed volume defined by receptacle 340 and window 345. The second coil 320 may be positioned within receptacle 340 to be mutually inductively associated with the first coil 315 to complete the transformer arrangement therewith.

In the example shown, second coil 320 is formed by winding a conductive wire on a film, substrate, or circuit board 355 in a substantially parallel relation relative to the first coil 315 and sufficiently close thereto so that magnetic flux produced by the first coil 315 may inductively link with the second coil 320. Alternatively, second coil 320 is disposed within enclosure 305 without an underlying film, substrate or circuit board. In FIG. 10, second coil 320 is shown wound about the MEMS mirror die 200. End terminals 320A, 320B of second coil 320 may be connected to the two terminals of MEMS mirror die 200 via wire bonds 360A, 360B, respectively, so that voltages induced across end terminals 320A, 320B may be provided to MEMS mirror die 200 for use in driving oscillation of mirror 210. As with the case of the first coil 315, it will be appreciated that other techniques may be used to provide second coil 320 within sealed enclosure 305, and that second coil 320 may follow other wiring patterns and/or be located elsewhere within sealed enclosure 305 so long as mutual inductance is established between first coil 315 and second coil 320.

With further reference to FIG. 8, a first adhesive material 360, such as a sheet of double-sided adhesive tape, may be used to secure the sealed enclosure 305 to PCB 325. Likewise, a second adhesive material 365, which may be double-sided adhesive tape as the first adhesive material 360, may be used to affix the second coil 320 and the MEMS mirror die 200 within the receptacle 340 relative to each other. In the example shown, the sealed enclosure 305 is disposed directly above the first coil 315 on PCB 325 while the second coil 320 fixedly rests upon the base 340A of receptacle 340 such that first coil 315 and second coil 320 are separated by a distance defined by the thicknesses of the base 340A and the adhesive materials 360, 365. To prevent magnetic field distortion between the first coil 315 and the second coil 320, at least the base 340A of receptacle 340 and the adhesive materials 360, 365 may be made of materials that permit and do not impede the passing of magnetic fields. For example, receptacle 340, including base 340A and side walls 340B, may be made of glass or other transparent material that is transparent over a desired range of wavelengths, and manufactured by any number of techniques. As an example, receptacle 340 may be formed by drawing a sheet of heated glass using a die. Additionally, by constructing receptacle 340 from glass, the coefficient of thermal expansion of receptacle 340 and MEMS mirror die 200 may be relatively closely matched so as to avoid introducing any undesired strain or distortion of MEMS mirror die 200 as the temperature of MEMS mirror device 300 changes during operation. Furthermore, sealed enclosure 305 may provide an effective electrical barrier for high voltages and a dust free environment for MEMS mirror die 200 and second coil 320.

Window 345 allows light to enter sealed enclosure 305 and exit therefrom after being reflected off by mirror 210 of MEMS mirror die 200. Window 345 may be made of substantially transparent material over a predetermined range of wavelengths, such as glass, and may be adhesively attached to the top rim 340C of receptacle 340 to complete the enclosure of MEMS mirror die 200 and second coil 320 and provide an environment thereto near or at vacuum conditions. In other alternative embodiments, window 345 may be coated with or made of a different material from receptacle 340. Top rim 340C of receptacle 340 may be formed in a planar manner to provide a substantially planar surface for application of adhesive, and window 345 may be oversized, relative to the perimeter of the top rim 340C, to allow a low-precision alignment of window 345 to receptacle 340. Since window 345 is outside of receptacle 340, ambient air pressure present may force window 345 against receptacle 340, which may increase the reliability of the seal between window 345 and receptacle 340.

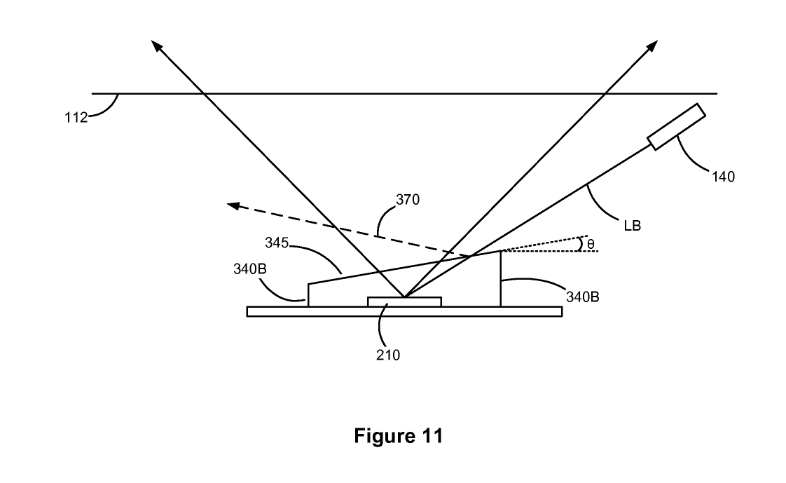

In an example embodiment, window 345 may be arranged in a tilted manner relative to the position of mirror 210 about extensions 220 of MEMS mirror die 200. For example, receptacle 340 may be formed in a manner such that a side wall 340B of receptacle 340 is taller than an opposite side wall 340B thereof, resulting in window 345 being attached to receptacle 340 at an angle θ, as shown in FIG. 11. By positioning window 345 at the angle θ, portions of light 370 reflected by window 345 may be deflected out of the plane of the light path of light beam LB entering sealed enclosure 305, impinging onto the mirror 210, reflecting therefrom, and exiting sealed enclosure 305. Accordingly, light portions 370 reflected off of window 345 may be angled away from photoconductive member 112 so as to avoid unwanted exposure of photoconductive member 112.

With the above example embodiments, a simple and cost-efficient way of packaging MEMS devices is provided, which supports the mechanical rigors of low-cost manufacturing processes. Example embodiments also introduce notions of rendering use of ceramic substrates to support MEMS components unnecessary in order to reduce cost, eliminating the need to pierce through walls of sealed enclosures within which MEMS components are disposed in order to simplify manufacturing and packaging processes, and delivering power into and/or out of sealed enclosures using one or more transformer configurations.

The description of the details of the example embodiments have been described in the context of electrophotographic imaging devices. However, it will be appreciated that the teachings and concepts provided herein are applicable to other systems employing optical scanners for scanning light beams. In addition, it will also be appreciated that teachings and concepts provided herein are applicable to other types of MEMS devices or any optical component that may benefit from being in a dust-free, pressure controlled environment, such as those used in the field of active optics.

The foregoing description of several example embodiments of the invention has been presented for purposes of illustration. It is not intended to be exhaustive or to limit the invention to the precise steps and/or forms disclosed, and obviously many modifications and variations are possible in light of the above teaching. It is intended that the scope of the invention be defined by the claims appended hereto.

What is claimed is:

1. An optical device, comprising:
an enclosure maintaining a substantially fixed pressure level therein and having a window for allowing light to enter and exit the enclosure;
a micro-electromechanical system (MEMS) optical device disposed within the enclosure, the MEMS optical device for reflecting, refracting or diffracting light incident thereon; and
a transformer having a first wire coil located outside the enclosure, and a second wire coil located within the enclosure and electrically coupled to the MEMS optical device, the transformer actuating the MEMS mirror.

2. The optical device of claim 1, wherein the substantially fixed pressure level is different from a pressure level outside the enclosure.

3. The optical device of claim 1, further comprising a circuit coupled between the second wire coil and the MEMS optical device.

4. The optical device of claim 1, wherein one or more portions of the enclosure is made of transparent material over a predetermined range of optical wavelengths.

5. The optical device of claim 1, wherein the window is arranged to deflect portions of light reflected thereby away from a plane defined by paths of light entering the enclosure, reflecting, refracting or diffracting from the MEMS optical device, and exiting the enclosure.

6. The optical device of claim 1, further comprising a board on which the first wire coil is disposed, the enclosure being attached to the board such that the first wire coil establishes mutual inductance with the second wire coil within the enclosure.

7. The optical device of claim 1, wherein the first and second wire coils are positioned in a substantially parallel relation relative to each other.

8. The optical device of claim 1, wherein the second wire coil and MEMS optical device are fixed within the enclosure.

9. The optical device of claim 1, further comprising a first circuit board or substrate on which the first wire coil and the enclosure are secured, the first wire coil being disposed between the first circuit board and the enclosure.

10. The optical device of claim 1, further comprising a wire bond coupled to each terminal of the MEMS optical device.

11. An assembly for a micro-electromechanical system (MEMS) device, comprising:
a sealed enclosure;
a MEMS component disposed within the sealed enclosure; and
a transformer arrangement having a first wire coil disposed outside the sealed enclosure, and a second wire coil disposed within the sealed enclosure and coupled to the MEMS component, the first and second wire coils being mutually inductively coupled to each other;
wherein applying energy to the first wire coil outside the sealed enclosure induces electrical energy in the second wire coil within the sealed enclosure to induce motion of the MEMS component.

12. The assembly of claim 11, further comprising a board on which the first wire coil is disposed, the board being positioned adjacent the sealed enclosure so that mutual inductance is established between the first and second wire coils.

13. The assembly of claim 12, wherein the seal enclosure is disposed on the first wire coil over the board.

14. The assembly of claim 1, wherein the sealed enclosure maintains therein a pressure level that is different from a pressure level outside the sealed enclosure.

15. The assembly of claim 11, wherein the sealed enclosure maintains therein a substantially constant pressure level.

16. The assembly of claim 11, wherein one or more portions of the sealed enclosure is made of a transparent material for optical wavelengths having a predetermined range.

17. The assembly of claim 11, wherein the sealed enclosure includes a base, the first wire coil being attached along an outer surface of the base and the second wire coil being attached to an inner surface of the base opposite the outer surface.

18. The assembly of claim 11, wherein the first and second wire coils are positioned in a substantially parallel relation relative to each other.

19. The assembly of claim 11, wherein the MEMS component comprises a MEMS optical component for reflecting, diffracting or refracting light.

20. The assembly of claim 11, further comprising a circuit of one or more electrical components disposed between the second wire coil and the MEMS component.

21. The assembly of claim 11, wherein the MEMS component comprises a deformable MEMS mirror.
